(19) United States
(12) Patent Application Publication
(10) Pub. No.: US 2020/0077796 A1
(43) Pub. Date: Mar. 12, 2020

(54) DRAWERS AND COMPONENTS FOR DRAWERS

(71) Applicant: Shane Robert MILES, Arundel (QLD) (AU)

(72) Inventor: Shane Robert MILES, Arundel (QLD) (AU)

(21) Appl. No.: 16/493,958

(22) PCT Filed: Mar. 15, 2018
(86) PCT No.: PCT/AU2018/050242

§ 371 Date: Sep. 13, 2019

(30) Foreign Application Priority Data
Mar. 17, 2017 (AU) 2017900938

(51) Int. Cl. A47B 88/919; A47B 88/437; A47B 88/477; H05K 7/14

(52) U.S. Cl. CPC A47B 88/919; A47B 88/437; A47B 2220/0091; H05K 7/1411; A47B 88/477

(57) ABSTRACT

A drawer system including: a drawer cabinet and a drawer mounted in said cabinet for forward and backward travel relative thereto; a power supply socket mounted in said drawer or said cabinet for providing power to the interior of said drawer at all positions between open and closed, the power supply socket including a pair of electrical conductors in electrical communication with a pair of contact means, said pair of contact means including a first contact half on or secured to said cabinet and a complementary second contact half on or secured to said drawer for movement therewith, said power supply socket being in electrical communication with said second contact half for electrical current can flow from said first contact half to said second contact half at all positions of the drawer between open and closed, the first half being in electrical communication with a power supply.

This invention relates to drawers and components for drawers. The invention has general application to drawers intended for use with heavy loads and drawers or drawer cabinets required for use in dirty or dusty locations, and has particular application to drawers for holding electrically operated equipment which is required to be stowed and drawn out for access.

Drawer cabinets for heavy loads typically include wheels mounted on opposite sides of the drawer and arranged to run on opposed complementary fixed tracks or guides mounted on the inside faces of the opposite sides of the cabinets and moveable guides operably interposed between the track of the draw and the tracks of the cabinet. Such an arrangement typically allows the drawer to be fully withdrawn from the cabinet.

When such drawers are used for supporting or holding electrically operated equipment, such as refrigerators and the like, a cable is normally strung from the back of the draw to the back of the cabinet. Such cables are often coiled to allow them to stretch and retract. However, the cable may snag on the moveable parts whereby the cable may be damaged, exposing the conductors to become an electrical hazard and fire risk. Additionally, continued flexure of the cable by virtue of the opening and closing of the draw, particularly near the attachment points, can cause loss of power to the drawer.

The present invention is aimed at providing drawers and which allows drawers to be fully accessible or at least almost fully accessible in a cabinet while at the same time being able provide electrical power for connection to electrically operated equipment to be supported by or held in the drawer.

With the foregoing in view, the invention in one aspect resides broadly in a drawer system including:

a drawer cabinet and a drawer mounted in said cabinet for forward and backward travel relative thereto;

a power supply socket mounted in said drawer or said cabinet for providing power the interior of said drawer at all positions between open and closed,

the power supply socket including a pair of electrical conductors in electrical communication with a pair of contact means, said pair of contact means including a first contact half on or secured to said cabinet and a complementary second contact half on or secured to said drawer for movement therewith, said power supply socket being in electrical communication with said second contact half for electrical current can flow from said first contact half to said second contact half at all positions of the drawer between open and closed, the first half being in electrical communication with a power supply.

Preferably, said power supply includes two pairs of electrical contact means with one pair being arranged to electrically connect the negative side of the power supply means and the other to electrically connect the positive side of the power supply means to thereby energise the conductors. While it is possible for supplying power with only one electrical contact means to be used on one side of the power supply socket, advantageously, use of the contact on each electrical side obviates the need for any wires to move with the drawer or drawing down electrical potential by running current through the frame. Moreover, the arrangement described herein affords the connection of a power supply separately from the vehicle power supply.

Preferably, one of said pair of halves includes a wheel or the like and the other includes a hump or recess whereby a predetermined opening force is required to open or close said drawer, or move said drawer away from said predetermined position. The predetermined opening force is a force sufficient to roll said wheel over said hump or into said recess and the predetermined closing force is a force sufficient to roll the drawer over the hump or out of the recess in the other direction, the wheel and hump arrangement constituting holding means for holding said draw at a predetermined position with respect to said cabinet. Advantageously, the drawer system with the holding means provides a mechanism which allows a person to access an open drawer safely when the vehicle in which it is mounted is parked on a slope.

Wires may be provided to the cabinet from the power supply and wires may be provided from the contacts to the power supply socket, however, the arrangement of the present invention provides that there are no wires between the drawer and the cabinet. Preferably, said power supply socket is mounted to or integral with holding means as previously described. In a preferred form, where the holding means includes a wheel on the drawer, it is preferred that the wheel include at least a part which is electrically conductive over the full circumference so that electrical contact can be made with a complementary contactor half in the recess or on the hump at any circumferential position of the wheel.

In this specification, terms such as vertical and horizontal, above and below, inside and outside, upper and lower, top and bottom and similar orientation terms are used to refer to various components and features when the drawer system is in its normal in use position for the purpose of providing a clear description of the invention and are not intended to limit the use of the drawer system to any particular orientation. Similarly, unless the context clearly requires otherwise, the term “half” used herein when referring to electrical contacts or holder components is not intended to refer to pure mathematical halves but rather to components in which two mating components are required to engage to achieve the function described.

In order that the invention may be more easily understood and put into practice reference will now be made to the accompanying drawings wherein:

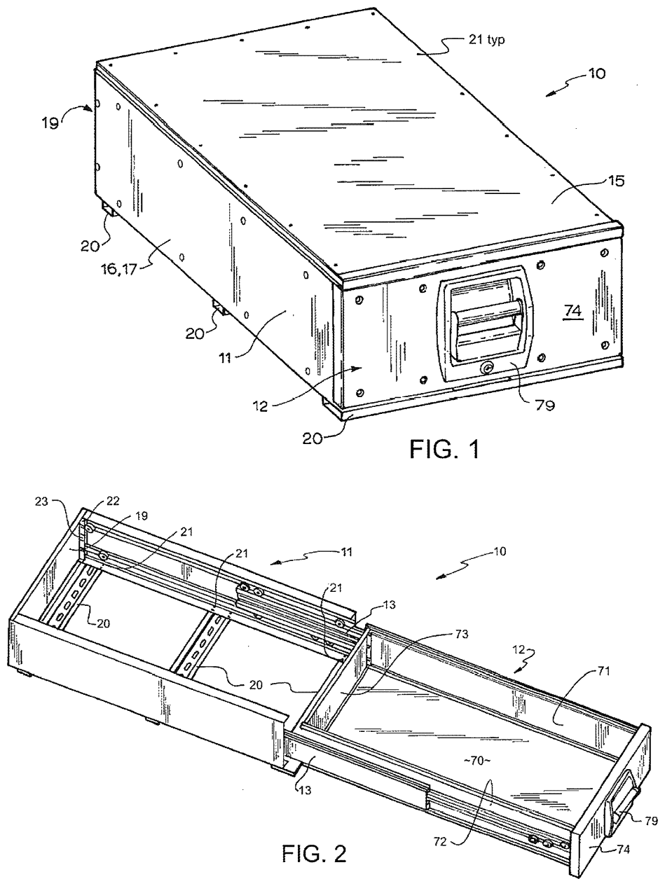

FIG. 1 is a pictorial representation of a single drawer cabinet according to the invention with the drawer closed;

FIG. 2 is a pictorial representation of the single drawer cabinet of FIG. 1 with the drawer fully open;

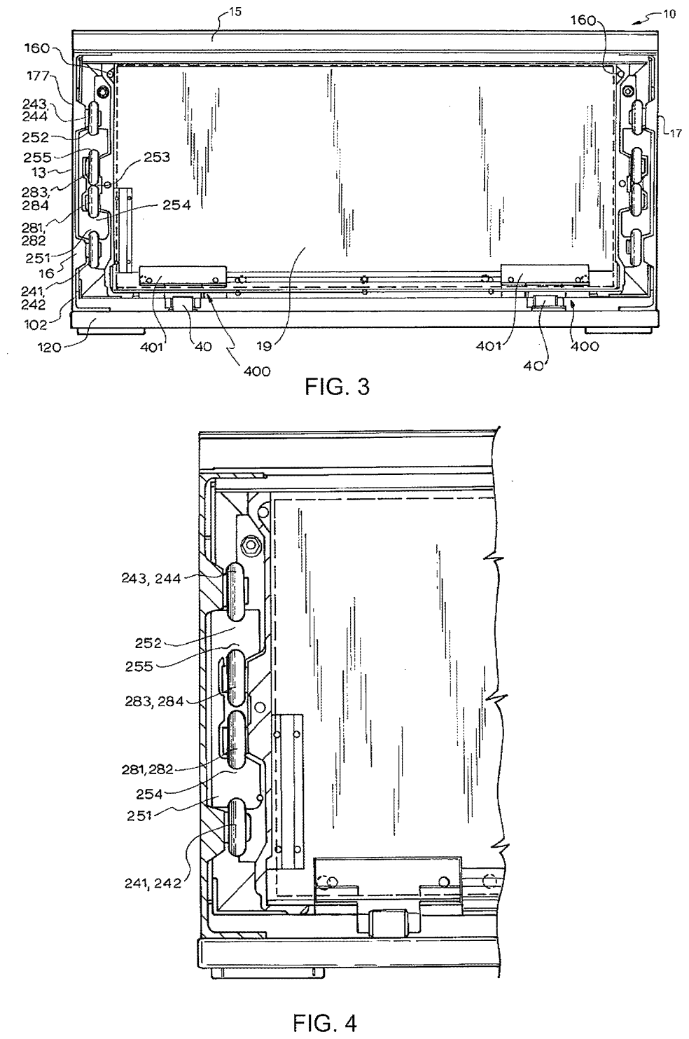

FIG. 3 is a sectional rear elevation of drawer cabinet according to the invention with showing an example of wheels and drawer stoppers or holders;

FIG. 4 is an enlarged sectional front elevation of part of the drawer of FIG. 3;

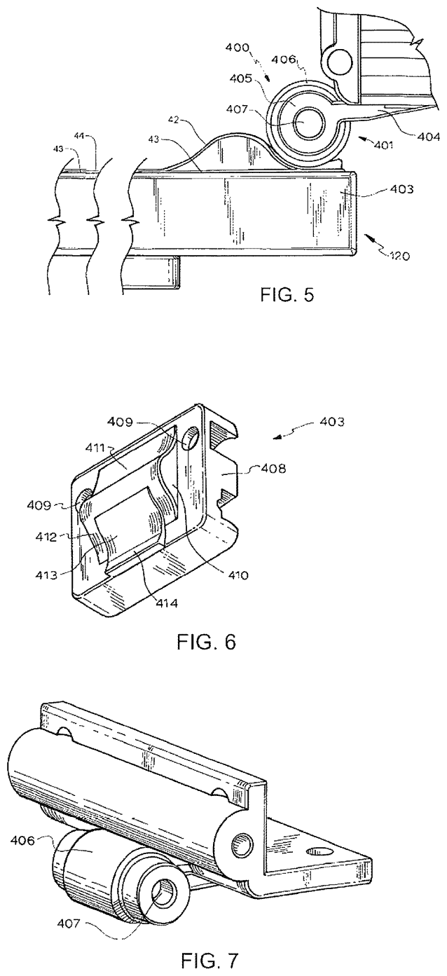

FIG. 5 is a sectional end elevation of part of the drawer system of FIG. 3 when the drawer is in the open position;

FIG. 6 is a pictorial representation of one of the stopper or holder components of the drawer of FIG. 3; and

FIG. 7 is a pictorial representation of another one of the stopper or holder components of the drawer of FIG. 3.

The drawer cabinet 10 illustrated in FIG. 1 includes a cabinet shell 11 and a drawer 12 mounted therein for forward and backward travel into and out of the shell on a runner 13. The shell has a bottom wall panel 14, an opposed upper wall panel 15 spaced from the bottom wall panel and two spaced apart side wall panels 16 and 17, only one of which is visible in FIG. 1, as well as a back wall panel 19.

The panels are secured together by screw threaded fasteners shown typically at 21 which engage in complementary screw threaded holes. In that respect, the selected wall panels have return or overlap at 90° which allows the screws to secure the one wall panel to an adjacent wall panel. The bottom wall is supported on spaced apart cross members 20 which extend laterally of the cabinet and support the bottom wall panel (floor panel) a small distance above the floor of the vehicle to which the cabinet system is to be fitted.

A runner 13 operates to support the drawer for opening and closing the drawer between rails on the drawer and rails on the cabinet as seen in FIG. 2, the top wall panel being removed so that the inside components are visible. The drawer 12 includes a bottom wall panel 70 which is similar to the bottom wall panel 14 of the cabinet and two spaced apart side wall panels 71 and 72 (not visible in FIG. 1) similar to side wall panels 16 and 17 of the cabinet as well as a back wall panel 73 and a front panel 74. A latch draw handle 79 is mounted in and secured to the front panel by threaded fasteners.

The side wall panels 71 and 72 are aluminium extrusions and each have an outwardly protruding and longitudinally extending bottom stiffening portion which is adapted to run within the lower recess of the shell sidewall and also an outwardly protruding and longitudinally extending upper stiffening rib 77 which is similarly adapted to run within the recess 32 provided in the shell sidewall. Advantageously, the bottom stiffening portion 76 and the upper stiffening rib 77 together with the recesses 31 and 32 allow the drawer and the shell to inter-engage thereby minimising the space taken up by the shell and the drawer walls while maintaining the necessary stiffness and strength of both panels. A number of screw threaded holes are provided in the side wall panels for securing the front panel and the bottom panel thereto in much the same manner as for the cabinet or shell 11.

The shell three spaced apart cross members 20 to the side wall panels at 21. The back wall panel 19 is secured to the side wall panels by threaded fasteners passing through holes 22 provided in both legs of an angle bracket 23 fitted in the respective corners.

The drawer and cabinet illustrated in FIGS. 3 and 4 shows the disposition of the wheels mounted to the cabinet, there being lower cabinet wheel at 241 and 242 and upper cabinet wheels at 243 and 244. The drawer has lower wheels at 281 and 282 and an upper wheel at 255. Advantageously, as can be more clearly seen in FIG. 4, the depth of each recess is selected such that only the convex tread portion of the wheels runs in the recess so that the side walls are clear of the recess and consequently cannot bind therewith. Moreover, the complementary convex treads together with the concave track result in the drawer being self-aligning in the cabinet.

The drawer and cabinet also has a stopper system mounted separately from the tracks and serve as conductors providing power to the drawer without the need use a power cable for same.

As can be seen in FIG. 5, the stopper system (or holder system) is arranged to stop forward movement of the drawer out of the cabinet and hold it in the outer open position and includes two spaced apart stopper units 400. Each stopper/holder unit includes two main components, a first component 401 mounted to the drawer (the drawer half) and a second component 403 mounted to front cross member 120 or the floor of the cabinet in cases where a floor is provided instead of cross members (the cabinet half). The stopper unit has an upper portion 42 of conductive material on a lower portion 43 of non-conductive material so as to provide electrical current to the wheels. The conductors on each set of runners are electrically connected to a respective positive and negative battery terminals or the active and neutral terminals of an alternating current power source.

The drawer half includes a mounting bracket 404 formed or non-conductive plastics material (although in other embodiments it may be formed of metal encapsulated in an insulating material) which is fastened to the back wall and bottom wall of the drawer by screws or bolts or other suitable fixing means, and a wheel made of a conductive material wheel which is mounted on an axle such as a bolt (not shown) passing through bores or passages 407 in the bracket for rotation relative thereto.

The cabinet half 403 includes a mounting bracket 408 which is fixed to the cross member 120 by screws or bolts extending through bores 409. The mounting bracket includes a stopper block 410 integrally formed therewith shaped as a longitudinal hump with a sloping lead face 411 and a similarly sloping exit face 112. A resting pad 413 formed of an electrical conductive material, preferably brass or aluminium is secured to the exit face and includes a stopper portion 414 at its exit end.

Suitably, the two halves are mounted such that as the drawer approaches the fully open position, the wheel 406 rolls up the lead face of the stopper block thereby lifting the rear end of the drawer slightly and rides over the hump and comes to rest on the resting pad against the stopper portion 414. Because there are two laterally spaced apart stopper units across the drawer and cabinet, the drawer lifts evenly as the wheels ride up the lead faces. It will be appreciated that another set of cabinet halves may be mounted at predetermined positions between the front of the cabinet and the rear of the cabinet to hold the drawer in other predetermined positions if desired.

Advantageously, the stopper system also serves as a power supply system for supplying electrical power to the inside of the drawer, such as electrical connection to the vehicle power supply. A power socket suited to the type of power being supplied is fastened to the inside of the drawer, preferably towards the back. In that respect, each conductive wheel of the drawer unit is connected by electrical cable to a respective terminal of the power socket. Similarly, when the cabinet is installed in a vehicle, the resting pad of one cabinet unit is connected by electrical cable to one terminal of the vehicle battery and the resting pad of the other cabinet unit is connected to the other terminal of the vehicle battery. The arrangement is such that as the drawer is opened, the conductive wheels run on the conductors, the circuit being completed and the electrical power being supplied to the power socket. Advantageously, the arrangement allows the drawer to be opened and closed without requiring any movement or dragging of a power supply cable and moreover results in the power being when the draw is in any position, making the drawer suitable for holding powered devices such as fridges.

It will be appreciated that while single drawer cabinets have been described, the invention can be used for multi drawer cabinets with side by side drawers or cabinets with drawers one above the other. Advantageously, the cabinets previously described can be simply mounted side by side and secured to each other or stacked one on top of the other and secured to each other. Alternatively, cabinet side walls of double height or triple height could be extruded in the same general form to accommodate multiple drawers.

The cabinet drawer system of the present invention provides many advantages over the currently available drawer systems. Firstly, the cabinet and drawer side walls comprise extruded aluminium panels which are designed to withstand heavy loads when used in vehicles being driven over rough terrain and to resist posting and bending. The side panels and the runner I designed so that they all into re-engage thereby minimising the space taken up by those panels thereby maximising drawer space. The side panels of the cabinet and the drawer form part of the slide mechanism in themselves so that a separate slide system is not required. The sliding system allows the drawer to extend completely beyond the cabinet thereby providing full upward access to the drawer and providing power to the drawer of the cabinet at any position between open and closed.

The foregoing description has been given by way of illustrative example of the invention and many modifications and variations which will be apparent to persons skilled in the art may be made without departing from the spirit and scope of the invention as hereinbefore described and claimed in the following claims.

1. A drawer system including:
a drawer cabinet and a drawer mounted in said cabinet for forward and backward travel relative thereto;
a power supply socket mounted in said drawer or said cabinet for providing power to the interior of said drawer at all positions between open and closed,
the power supply socket including a pair of electrical conductors in electrical communication with a pair of contact means, said pair of contact means including a first contact half on or secured to said cabinet and a complementary second contact half on or secured to said drawer for movement therewith, said power supply socket being in electrical communication with said second contact half for electrical current can flow from said first contact half to said second contact half at all positions of the drawer between open and closed, the first half being in electrical communication with a power supply.

2. The drawer system according to claim 1, wherein said power supply includes two pairs of electrical contact means with one pair being arranged to electrically connect the negative side of the power supply means and the other to electrically connect the positive side of the power supply means to thereby energize the conductors.

3. The drawer system according to claim 1, wherein electrical contact is provided on each electrical side.

4. The drawer system according to claim 1, wherein one of said pair of halves includes a wheel or the like and the other includes a hump or recess constituting holding means for holding said draw at a predetermined position with respect to said cabinet.

5. The drawer system according to claim 4, wherein said power supply socket is mounted to or integral with said holding means.

6. The drawer system according to claim 4, wherein said wheel is provided on said drawer, said wheel including at least a part which is electrically conductive over the full circumference whereby electrical contact can he made with a complementary contactor half in the recess or on the hump at any circumferential position of the wheel.

7. The drawer system according to claim 2, wherein electrical contact is provided on each electrical side.

8. The drawer system according, to claim 2, wherein one of said pair of halves includes a wheel or the like and the other includes a hump or recess constituting holding means for holding said draw at a predetermined position with respect to said cabinet.

9. The drawer system according to claim 2, wherein one of said pair of halves includes a wheel or the like and the other includes a hump or recess constituting holding means for holding said draw at a predetermined position with respect to said cabinet.

10. The drawer system according to claim 5, wherein said wheel is provided on said drawer, said wheel including at least a part which is electrically conductive over the full circumference whereby electrical contact can be made with a complementary contactor half in the recess or on the hump at any circumferential position of the wheel.
